(19) United States
(12) Patent Application Publication
(10) Pub. No.: US 2026/0282406 A1
(43) Pub. Date: Sep. 17, 2026

(54) SEMICONDUCTOR DEVICE

(71) Applicant: Vanguard International Semiconductor Corporation, Hsinchu (TW)

(72) Inventors: Wen-Shan LEE, Hsinchu City (TW); Chen-Dong TZOU, Taipei City (TW); Chung-Yeh LEE, Xinpu Township (TW); Fu-Hsin CHEN, Zhudong Township (TW)

(73) Assignee: Vanguard International Semiconductor Corporation, Hsinchu (TW)

(21) Appl. No.: 19/081,662

(22) Filed: Mar. 17, 2025

(51) Int. Cl. H10D 12/00; H10D 62/60

(52) U.S. Cl. CPC H10D 12/411; H10D 62/60

(57) ABSTRACT

A semiconductor device is provided. The semiconductor device includes a substrate structure, a well region, an emitter contact region, a collector contact region, an isolation doped region, trenches and a gate electrode. A top epitaxial layer of the substrate structure has a second conductivity type and includes a first region and a second region having different doped concentrations. The well region and the isolation doped region are located outside the first region and have a first conductivity type. The emitter contact region is disposed on the well region. The collector contact region is disposed in the first region. The emitter contact region and the collector contact region have opposite conductivity types. The isolation doped region is located between the well region and the collector contact region. The trenches extend from the emitter contact region to the isolation doped region. The gate electrode fills the trenches.

### BACKGROUND OF THE INVENTION

### Field of the Invention

The present invention relates to a semiconductor device, and in particular it relates to a semiconductor device that includes a trench gate and a three-dimensional (3D) channel structure.

### Description of the Related Art

The semiconductor industry continues to improve the integration density of electronic components by continuously reducing their minimum component size, thereby allowing more components to be integrated into a given area. For example, a complementary metal-oxide semiconductor (CMOS) field effect transistor (FET) is the most basic and widely used component in integrated circuit manufacturing. It has the advantages of low power consumption, easy manufacturing, and small size. A laterally-diffused metal-oxide semiconductor (LDMOS) field effect transistor (FET) is often used in high-voltage power integrated circuits to meet the requirements of high voltage resistance and power control. In addition, the process of laterally diffused metal-oxide semiconductor (LDMOS) components is easily compatible with that of complementary metal-oxide semiconductor (CMOS) components.

However, conventional LDMOS and CMOS components generally use a planar gate structure located on the top surface of the semiconductor substrate, which makes the conventional LDMOS and CMOS components unable to fully meet requirements in terms of turn-on resistance, forward current, channel mobility, etc.

### BRIEF SUMMARY OF THE INVENTION

An embodiment of the disclosure provides a semiconductor device. The semiconductor device includes a substrate structure, a well region, an emitter contact region, a collector contact region, an isolation doped region, trenches, and a gate electrode. The substrate structure includes a top epitaxial layer. The top epitaxial layer includes a first region and a second region. The well region is located outside the first region of the top epitaxial layer. The well region has a first conductivity type, and the top epitaxial layer has a second conductivity type. The emitter contact region is disposed on the well region. The collector contact region is disposed in the first region of the top epitaxial layer. The emitter contact region and the collector contact region have opposite conductivity types. The isolation doped region is disposed outside the first region of the top epitaxial layer and located between the well region and the collector contact region, and the isolation doped region has a first conductivity type. The trenches are disposed in the substrate structure. The trenches extend from the emitter contact region to the isolation doped region along a first direction. Bottom surfaces of the trenches are higher than a bottom surface of the emitter contact region and a bottom surface of the isolation doped region. The gate electrode is disposed on the substrate structure and fills the trench. The distance between the collector contact region and the gate electrode is greater than the distance between the emitter contact region and the gate electrode. The first region and the second region of the top epitaxial layer have different doping concentrations.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure;

FIG. 2 is a partial three-dimensional schematic diagram of the semiconductor device shown in FIG. 1 in accordance with some embodiments of the disclosure;

FIG. 3 is a schematic cross-sectional view taken along the line B-B and the line B′-B′ of FIG. 2;

FIGS. 4, 5, 6, 7, 8A, 9A, and 10A are cross-sectional views of intermediate stages of forming the semiconductor device of FIG. 1 in accordance with some embodiments of the disclosure; and

FIGS. 8B, 9B, and 10B are three-dimensional schematic diagrams of intermediate stages of forming a channel region of the semiconductor device of FIG. 1 in accordance with some embodiments of the disclosure.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to a semiconductor device including a trench gate and a three-dimensional (3D) channel structure and a method for forming the same. There are multiple trenches in a substrate of the semiconductor device. A gate is located on the substrate and fills the trenches, thereby forming a three-dimensional channel structure between the trench gates to increase the channel width. In addition, the channel mobility can be increased by changing the crystal plane of the sidewall of the three-dimensional channel structure, thereby improving the on-resistance and forward current of the semiconductor device. Furthermore, the drift region of the semiconductor device may have multiple regions. The resistance of the drift region of the semiconductor device may be further reduced by adjusting the doping concentrations of the regions. The semiconductor device disclosed herein is applicable to a lateral insulated gate bipolar transistor (LIGBT) element.

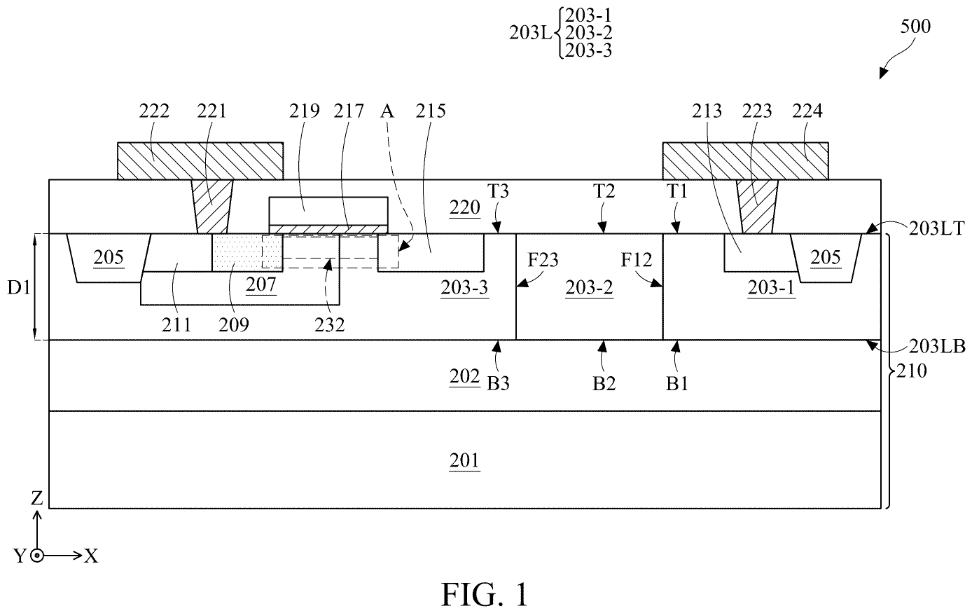

FIG. 1 is a schematic cross-sectional view of a semiconductor device 500 in accordance with some embodiments of the disclosure. In some embodiments, the semiconductor device 500 may be a lateral insulated gate bipolar transistor (LIGBT). In some embodiments, the semiconductor device 500 may include a substrate structure 210, a well region 207, an emitter contact region 209, a collector contact region 213, an isolation doped region 215, trenches 232, and a gate electrode 219.

In some embodiments, the substrate structure 210 may include a bottom layer 201, a first epitaxial layer 202, and a second epitaxial layer 203L stacked sequentially from bottom to top. In some embodiments, the bottom layer 201 may be doped with dopants to have a second conductivity type. When the second conductivity type is N type, the dopant with the second conductivity type may include phosphorus (P), arsenic (As), antimony (Sb) or other suitable dopants. Furthermore, the doping concentration of the bottom layer 201 is about 10¹⁹-10²¹ atoms/cm³. The bottom layer 201 may be regarded as an N-type heavily doped semiconductor substrate.

The first epitaxial layer 202 is disposed on the bottom layer 201. In some embodiments, the first epitaxial layer 202 may be doped with dopants to have a first conductivity type that is opposite to the second conductivity type. Furthermore, the dopant with the first conductivity type may include aluminum (Al), boron (B), boron difluoride (BF₂) or other suitable dopants. For example, when the bottom layer 201 is an N-type bottom layer 201, the first epitaxial layer 202 is a P-type epitaxial layer 202. Furthermore, the doping concentration of the first epitaxial layer 202 is about 10¹⁷-10¹⁸ atoms/cm³.

The second epitaxial layer 203L is disposed and stacked on the first epitaxial layer 202. In some embodiments, the second epitaxial layer 203L may be doped with dopants to have the second conductivity type. For example, when the bottom layer 201 is an N-type bottom layer 201, the second epitaxial layer 203L is an N-type epitaxial layer 203L. Furthermore, the doping concentration of the second epitaxial layer 203L (e.g., about 10¹⁵-10¹⁶ atoms/cm³) is lower than the doping concentration of the bottom layer 201 (e.g., about 10¹⁹-10²¹ atoms/cm³). For example, when the bottom layer 201 is an N-type heavily doped (N⁺) bottom layer 201, the second epitaxial layer 203L is an N-type lightly doped (N⁻) epitaxial layer 203L. In the applications of the lateral insulated gate bipolar transistors, the second epitaxial layer 203L having the second conductivity type may serve as a drift region of the semiconductor device 500. In some embodiments, the second epitaxial layer 203L is located at the topmost layer of the substrate structure 210, and may also be referred to as a top epitaxial layer 203L. The first epitaxial layer 202 is located as the middle layer of the substrate structure 210, and may also be referred to as a middle epitaxial layer 202.

As shown in FIG. 1, the second epitaxial layer 203L may include a plurality of regions 203-1, 203-2, and 203-3 arranged side by side along the X-direction (the channel length direction). In the Z-direction (the vertical direction), the depths of the regions 203-1, 203-2, and 203-3 may all be the same as the thickness D1 of the second epitaxial layer 203L. In some embodiments, a top surface T1 of the region 203-1, a top surface T2 of the region 203-2, and a top surface T3 of the region 203-3 may all be coplanar, and they may all be different portions of the top surface 203LT of the second epitaxial layer 203L. The bottom surface B1 of the region 203-1, the bottom surface B2 of the region 203-2, and the bottom surface B3 of the region 203-3 may all be coplanar, and they may all be different portions of the bottom surface 203LB of the second epitaxial layer 203L. Furthermore, the interface F12 between the region 203-2 and the region 203-1 and the interface F23 between the region 203-2 and the region 203-3 both extend from the top surface 203LT of the top epitaxial layer 203L to the bottom surface 203LB of the top epitaxial layer 203L along the Z-direction. Therefore, the first epitaxial layer 202 may be in contact with the first region 203-1, the second region 203-2, and the third region 203-3 of the second epitaxial layer 203L at the same time.

In some embodiments, the two adjacent regions among the region 203-1, the region 203-2, and the region 203-3 may have different doping concentrations according to the design of device electrical performances (e.g., on-resistance or breakdown voltage). For example, the doping concentrations of the region 203-1, the region 203-2, and the region 203-3 may increase gradually. In other words, the doping concentration of the region 203-1 is lower than the doping concentration of the region 203-2, and the doping concentration of the region 203-2 is lower than the doping concentration of the region 203-3. In this embodiment, the doping concentration of the region 203-1 may be the same as the original doping concentration of the second epitaxial layer 203L.

In some embodiments, the doping concentration of the region 203-2 may be greater than or less than the doping concentrations of the regions 203-1 and 203-3. In this embodiment, the region 203-1 and the region 203-3 may also have the same doping concentration. The second epitaxial layer 203L may have any number of regions with different doping concentrations and is not limited to the embodiments of the present disclosure.

In some embodiments, the composition of the bottom layer 201, the first epitaxial layer 202, and the second epitaxial layer 203L may be silicon carbide (SiC) or silicon (Si). In some embodiments, the first epitaxial layer 202 and the second epitaxial layer 203L may be formed by epitaxial processes. The epitaxial processes include metal organic chemical vapor deposition (MOCVD), plasma-enhanced CVD (PECVD), molecular beam epitaxy (MBE), hydride vapor phase epitaxy (HVPE), liquid phase epitaxy (LPE), chloride vapor phase epitaxy (Cl-VPE), other suitable epitaxial growth processes, or a combination thereof.

The well region 207 of the semiconductor device 500 is disposed in the region 203-3 of the second epitaxial layer 203L. In some embodiments, the well region 207 may be doped with dopants to have the first conductivity type. For example, when the bottom layer 201 is an N-type bottom layer 201, the well region 207 is a P-type well region 207. Furthermore, the doping concentration of the well region 207 may be the same as the doping concentration of the first epitaxial layer 202, for example, about 10¹⁷-10¹⁸ atoms/cm³.

The emitter contact region 209 of the semiconductor device 500 is disposed on the well region 207. In some embodiments, the emitter contact region 209 may be doped with dopants to have the second conductivity type. For example, when the bottom layer 201 is an N-type bottom layer 201, the emitter contact region 209 is an N-type contact region 209. Furthermore, the doping concentration of the emitter contact region 209 may be the same as the doping concentration of the bottom layer 201, for example, about 10¹⁹-10²¹ atoms/cm³.

The semiconductor device 500 further includes a bulk contact region 211. The substrate contact region 211 is disposed on the well region 207. In some embodiments, the body contact region 211 may be adjacent to the emitter contact region 209. In some embodiments, the body contact region 211 may be doped with dopants to have the same conductivity type as the well region 207. For example, when the well region 207 has the first conductivity type (for example, the P-type well region 207), the body contact region 211 may have the first conductivity type (for example, the P-type body contact region 211). Furthermore, the doping concentration of the substrate contact region 211 is greater than the doping concentration of the well region 207, for example, about 10¹⁹-10²¹ atoms/cm³. For example, when the well region 207 is a P-type well region 207, the substrate contact region 211 is a P-type heavily doped (P⁺) region 211 to serve as a pick-up doped region of the well region 207.

The collector contact region 213 of the semiconductor device 500 is disposed in the region 203-1 of the second epitaxial layer 203L, such that the region 203-2 is located between the well region 207 and the collector contact region 213. In some embodiments of lateral insulated gate bipolar transistor applications, the emitter contact region 209 and the collector contact region 213 of the semiconductor device 500 have opposite conductivity types. In some embodiments, the body contact region 211 may be doped with dopants to have the first conductivity type. For example, when the bottom layer 201 is an N-type bottom layer 201, the collector contact region 213 is a P-type collector contact region 213. Furthermore, the doping concentration of the collector contact region 213 may be the same as the doping concentration of the body contact region 211, for example, about 10¹⁹-10²¹ atoms/cm³. Therefore, the collector contact region 213 is a P-type heavily doped (P⁺) region 213.

The isolation doped region 215 of the semiconductor device 500 is disposed in the region 203-3 of the second epitaxial layer 203L and is located between the well region 207 and the collector contact region 213. In some embodiments, the isolation doped region 215 may be doped with dopants to have the first conductivity type. For example, when the bottom layer 201 is an N-type bottom layer 201, the isolation doped region 215 is a P-type isolation doped region 215. Furthermore, the doping concentration of the isolation doped region 215 may be the same as the doping concentrations of the body contact region 211 and the collector contact region 213, for example, about 10¹⁹-10²¹ atoms/cm³. Therefore, the isolation doped region 215 is a P-type heavily doped (P⁺) region 215.

As shown in FIG. 1, the isolation doped region 215 is located close to an edge of a subsequent gate electrode 219 to reduce the surface electric field at the edge of the gate electrode 219, thereby increasing the breakdown voltage of the semiconductor device 500.

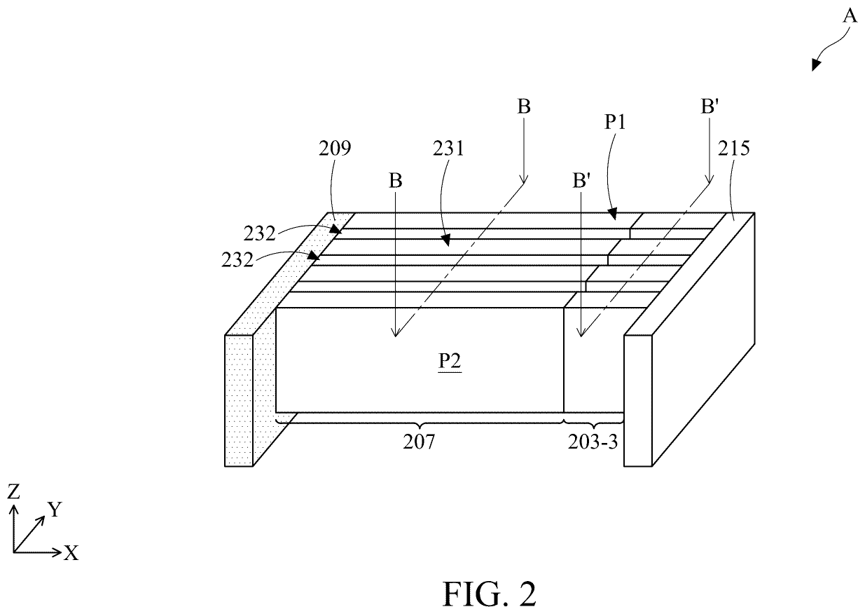

As shown in FIG. 1, the semiconductor device 500 further includes a plurality of trenches 232 disposed in the second epitaxial layer 203L of the substrate structure 210 (as shown in the area A, and the detailed structure of the trenches 232 can be referred to FIG. 2). In some embodiments, the trenches 232 are disposed in the region 203-3 of the second epitaxial layer 203L. The trenches 232 extend laterally from the emitter contact region 209 to the isolation doped region 215 along a first direction (for example, the X-axis direction). For example, the trenches 232 continuously extend from adjacent to the right side surface of the emitter contact region 209 to adjacent to the left side surface of the isolation doped region 215. In addition, the bottom surfaces of the trenches 232 are higher (e.g., closer to the top surface 203LT of the second epitaxial layer 203L) than the bottom surfaces of the emitter contact region 209 and the bottom surfaces of the isolation doped region 215.

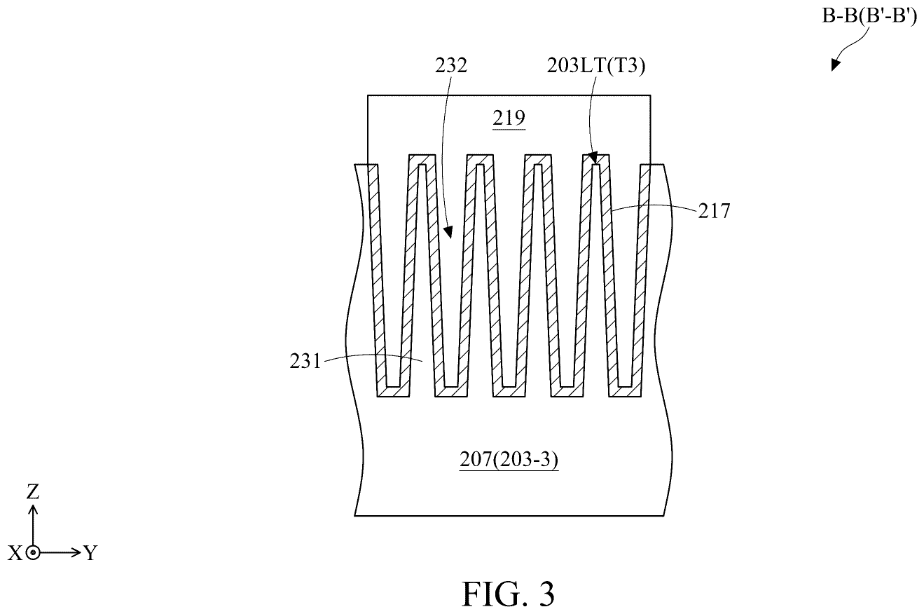

The gate electrode 219 of the semiconductor device 500 is disposed on the substrate structure 210 and filled in the trenches 232. The gate dielectric layer 217 is disposed below the gate electrode 219 and conformally formed on the sidewalls and bottom surfaces of the trenches 232 and the top surface of the substrate structure 210 (i.e., the top surface 203LT of the second epitaxial layer 203L and the top surface T3 of the region 203-3) (the detailed structure of the gate electrode 219 and the trenches 232 can be referred to FIG. 3). In this embodiment, the distance between the collector contact region 213 and the gate electrode 219 is greater than the distance between the emitter contact region 209 and the gate electrode 219. In other embodiments, the distance between the collector contact region 213 and the gate electrode 219 may be equal to the distance between the emitter contact region 209 and the gate electrode 219.

In addition, the semiconductor device 500 further includes a shallow trench isolation (STI) structure 205 disposed in the substrate structure 210, such as in the second epitaxial layer 203L. In accordance with some embodiments of the disclosure, the top surface of the emitter contact region 209, the top surface of the isolation doped region 215, the top surface of the collector contact region 213 and the top surface of the shallow trench isolation structure 205 are all located on the same plane, for example, all located at the top surface of the substrate structure 210 (i.e., the top surface 203LT of the second epitaxial layer 203L).

The semiconductor device 500 further includes an interlayer dielectric layer 220. The interlayer dielectric layer 220 may be entirely disposed on the substrate structure 210 and cover the gate electrode 219. In some embodiments, the interlayer dielectric layer 220 may include silicon oxide, silicon nitride, silicon oxynitride, phospho-silicate glass (PSG), boro-phospho-silicate glass (BPSG), or a combination thereof. In some embodiments, the interlayer dielectric layer 220 may be formed by using a conformably deposition process, an oxidation process, other suitable formation processes, and a subsequent patterning process. In some embodiments, the oxidation process may be thermal oxidation or other suitable processes. In some embodiments, the deposition process may be a physical vapor deposition (PVD) process, a chemical vapor deposition (CVD) process, a plasma assisted chemical vapor deposition (PECVD), other suitable processes, or a combination thereof.

The semiconductor device 500 further includes an emitter contact 221 and a collector contact 223 disposed on the second epitaxial layer 203L. The emitter contact 221 passes through the interlayer dielectric layer 220 from above the interlayer dielectric layer 220 to cover and electrically connect the emitter contact region 209 and the body contact region 211 along the Z-direction. The collector contact 223 passes through the interlayer dielectric layer 220 from above the interlayer dielectric layer 220 to cover and electrically connect the collector contact region 213 along the Z-direction.

As shown in FIG. 1, the semiconductor device 500 further includes an emitter electrode 222 and a collector electrode 224 disposed on the second epitaxial layer 203L. The emitter electrode 222 is electrically coupled to the emitter contact region 209 and the body contact region 211 through the emitter contact 221. The collector electrode 224 is electrically coupled to the collector contact region 213 through the collector contact 223. In some embodiments, the emitter electrode 222 and the collector electrode 224 may include copper, silver, gold, aluminum, tungsten, other suitable metal materials, or a combination thereof. In some embodiments, the emitter electrode 222 and the collector electrode 224 may include the same material or different materials. In some embodiments, the emitter electrode 222 and the collector electrode 224 may be formed by a deposition process and a subsequent patterning process. In some embodiments, the deposition process may include a physical vapor deposition process, a chemical vapor deposition process, other suitable processes, or a combination Thereof.

FIG. 2 is a three-dimensional schematic diagram of the area A of the semiconductor device shown in FIG. 1 in accordance with some embodiments of the disclosure. FIG. 3 is a cross-sectional schematic diagram taken along the line B-B and the line B′-B′ of FIG. 2. In FIG. 2, the line B-B passes through the well region 207, and the line B′-B′ passes through the second epitaxial layer 203L. For illustration, the gate electrode 219 and the gate dielectric layer 217 are not drawn in the three-dimensional schematic diagram of FIG. 2. As shown in FIGS. 2 and 3, the substrate structure 210 of the semiconductor device 500 includes a plurality of strip structures 231, which extend along the first direction (e.g., the X-direction) from in contact with the right side surface of the emitter contact region 209, across the well region 207 and a portion of the second epitaxial layer 203L, and laterally extend to in contact with the left side surface of the contact isolation doped region 215. The strip structures 231 and the trenches 232 are alternately arranged along the second direction (e.g., the Y-direction). The bottom surfaces of the strip structures 231 are higher (e.g., closer to the top surface 203LT of the second epitaxial layer 203L) than the bottom surface of the emitter contact region 209 and the bottom surface of the isolation doped region 215. In addition, the top surfaces of the strip structures 231, the top surface of the emitter contact region 209 and the top surface of the isolation doped region 215 are all located on the same plane. Moreover, the top surfaces of the strip structures 231 and the top surface of the shallow trench isolation structure 205 are also located on the same plane. As shown in the cross-sectional schematic diagram of FIG. 3, the gate dielectric layer 217 is conformally formed on the sidewalls and the top surfaces of the strip structures 231 and the bottom surfaces of multiple trenches 232. The gate electrode 219 is filled in the trenches 232 and is located on the top surfaces of the strip structures 231. The gate electrode 219 may have a flat top surface.

In some embodiments, the composition of the substrate structure 210 or the second epitaxial layer 203L is, for example, silicon carbide (SiC). The sidewall P2 of the strip structure 231 may be the (0, −3, 3, −8) crystal plane of silicon carbide, the (1, 1, −2, 0) crystal plane of silicon carbide or other crystal planes having low interface state density, The top surface P1 of the strip structure 231 is the (0, 0, 0, 1) crystal plane of silicon carbide. Compared with the (0, 0, 0, 1) crystal plane of silicon carbide, the (0, −3, 3, −8) crystal plane and the (1, 1, −2, 0) crystal plane of silicon carbide have lower interface state density and higher free electrons, which greatly increases the electron channel mobility. The channel mobility of the (0, −3, 3, −8) crystal plane may be about 4 to 5 times that of the (0, 0, 0, 1) crystal plane. The channel mobility of the (1, 1, −2, 0) crystal plane may be about 2 times that of the (0, 0, 0, 1) crystal plane. In addition, the sidewalls P2 of the strip structures 231 may increase the channel width (e.g., in the Y-direction) by several times, thereby significantly improving the channel mobility of the semiconductor device 500, and further reducing the characteristic on-resistance (Rₒₙₛₚ) and increasing the forward current.

In another embodiment, the second epitaxial layer 203L is composed of silicon, for example. The sidewall P2 and the top surface P1 of the strip structure 231 are both the (1, 0, 0) crystal plane of silicon. Although the crystal plane of the sidewall of the strip structure 231 formed of silicon cannot be used to improve the channel mobility, the channel width (for example, in the Y-direction) can still be increased several times by the multiple sidewalls P2 of the multiple strip structures 231 to improve the channel mobility of the semiconductor device 500, thereby reducing the characteristic on-resistance (Rₒₙₛₚ) and increasing the forward current.

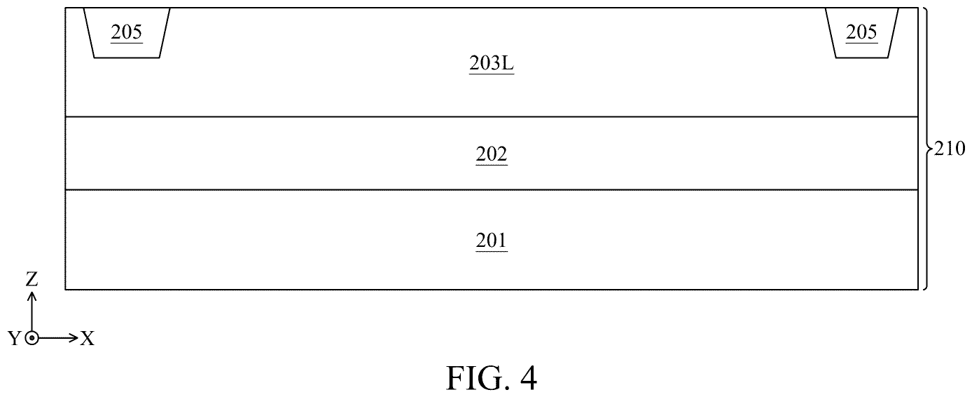

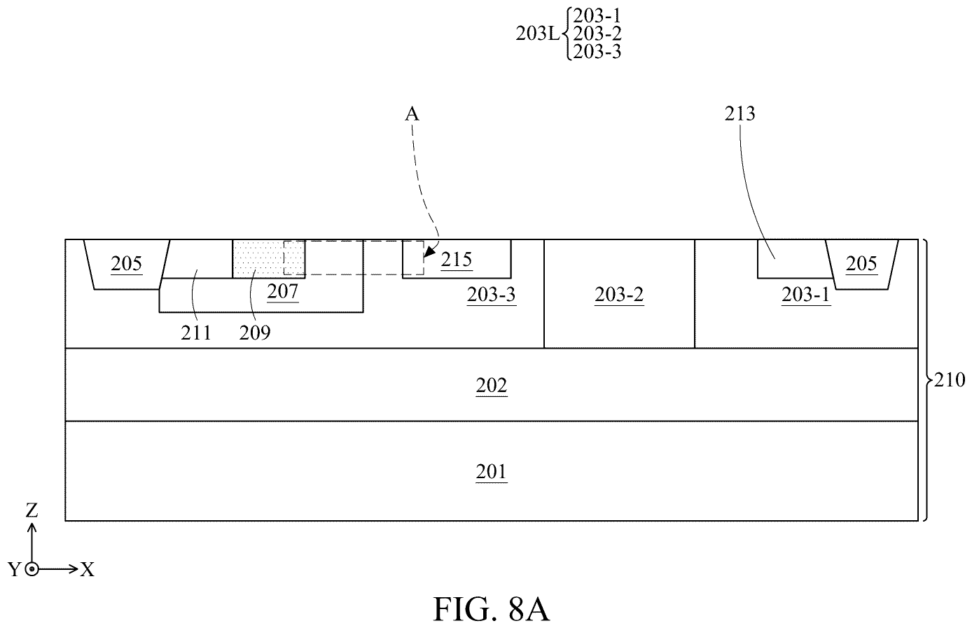

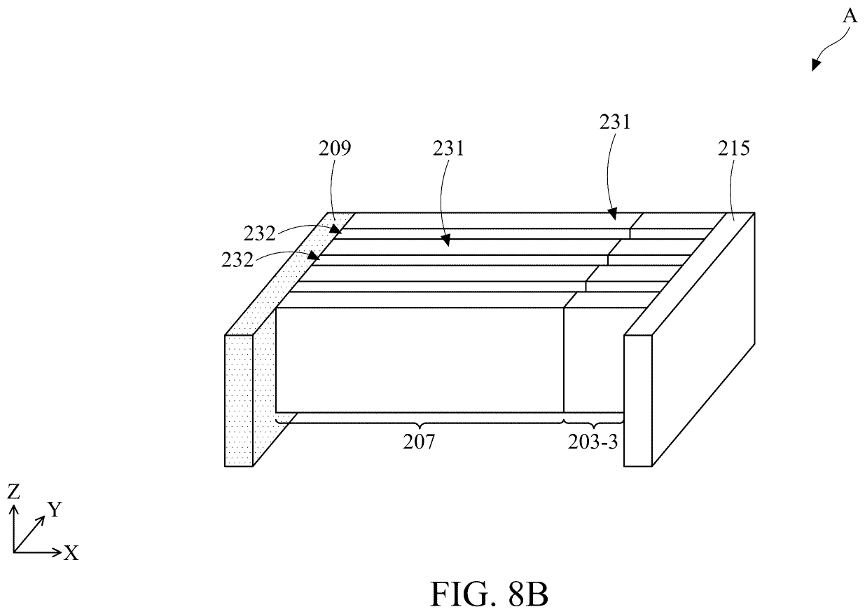

Next, a method for forming the semiconductor device 500 in accordance with some embodiments of the disclosure is described. FIGS. 4, 5, 6, 7, 8A, 9A, and 10A are cross-sectional views of intermediate stages of forming the semiconductor device 500 of FIG. 1 in accordance with some embodiments of the disclosure. FIGS. 8B, 9B, and 10B are three-dimensional schematic diagrams of intermediate stages of forming the area A of the semiconductor device 500 of FIG. 1 in accordance with some embodiments of the disclosure, in which the reference numbers the same or similar to those in FIG. 1 denote the same or similar elements.

As shown in FIG. 4, first, a substrate structure 210 is provided. The substrate structure 210 includes a bottom layer 201, a first epitaxial layer 202, and a second epitaxial layer 203L stacked in sequence from bottom to top. A shallow trench isolation structure 205 is formed in the second epitaxial layer 203L by photolithography, etching, filling and chemical mechanical planarization processes.

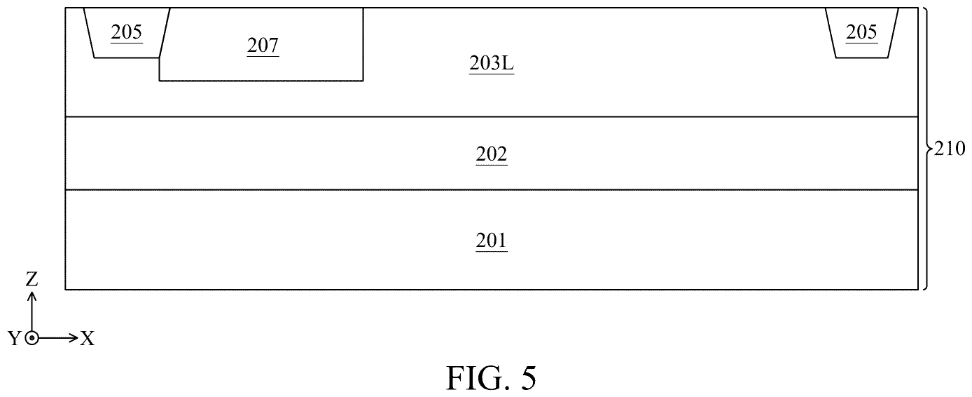

Next, as shown in FIG. 5, an ion implantation process is performed using a mask to implant the dopants of the first conductive type (P-type) into the second epitaxial layer 203L, thereby forming a well region 207.

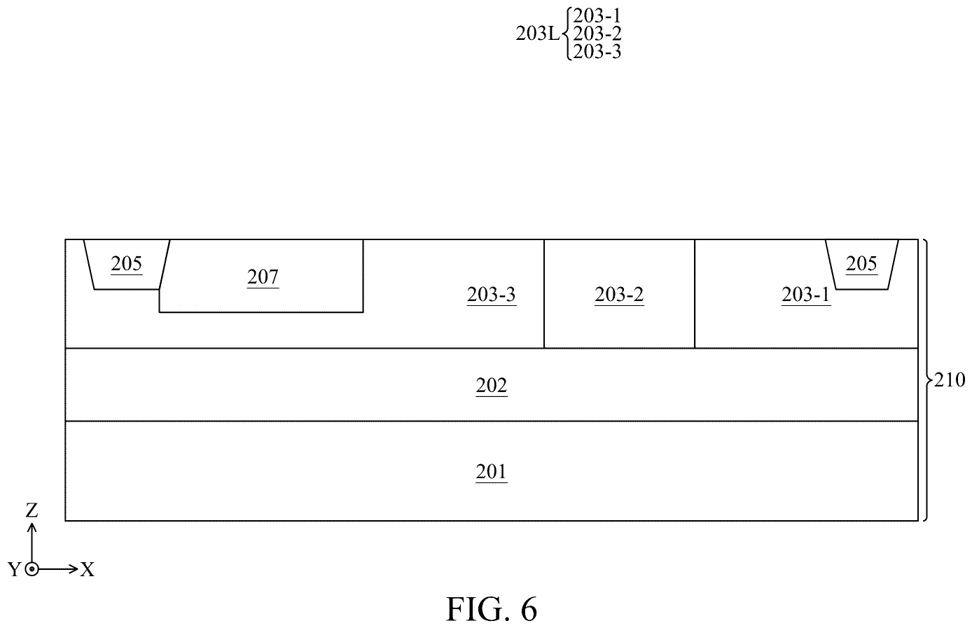

Next, as shown in FIG. 6, multiple ion implantation processes are performed using a plurality of masks to implant second conductivity type (N-type) dopants into different regions within the second epitaxial layer 203L to respectively form regions 203-1, 203-2, and 203-3. For example, a mask may be used to cover the region 203-3, and then an ion implantation process may be performed to implant the dopants of the second conductivity type (N-type) into the regions 203-1 and 203-2. Next, another mask may be used to cover the regions 203-2 and 203-3, and then an ion implantation process may be performed to implant the dopants of the second conductivity type (N-type) into the region 203-1, so as to form regions 203-1, 203-2, and 203-3 having different doping concentrations. In this embodiment, the doping concentration of the region 203-1 is greater than the doping concentration of the region 203-2, and the doping concentration of the region 203-2 is greater than the doping concentration of the region 203-3. The doping concentrations of the regions 203-1, 203-2, and 203-3 may be adjusted arbitrarily and are not limited to the disclosed embodiments. In some embodiments, the doping concentration of the region 203-3 is equal to the doping concentration of the second epitaxial layer 203L. Also, the well region 207 is located in the region 203-3.

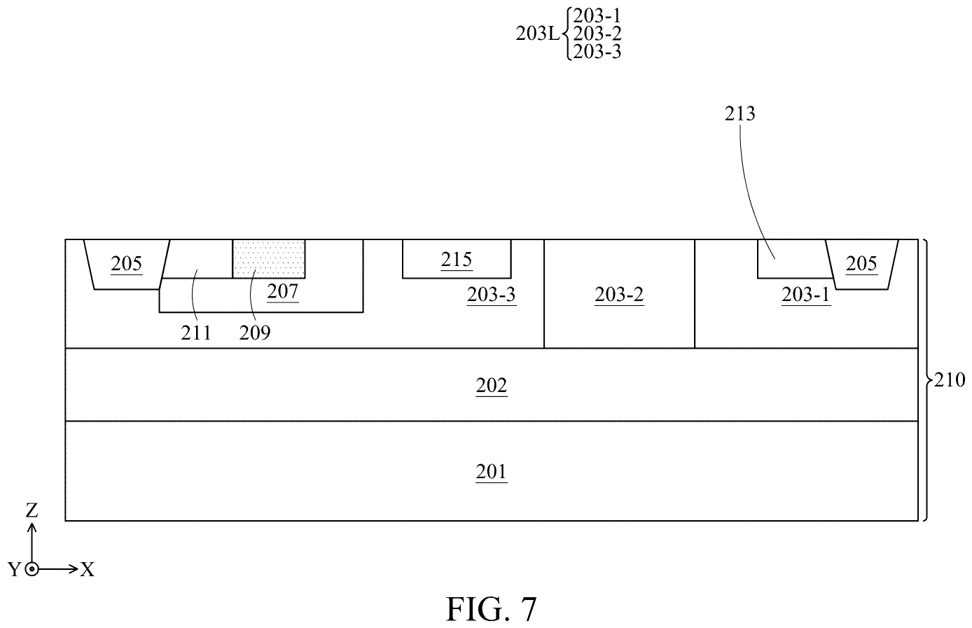

Next, as shown in FIG. 7, another ion implantation process is performed using another mask to implant the dopants of the first conductivity type (P-type) into the well region 207 and the region 203-1 of the second epitaxial layer 203L to form a body contact region 211 and an isolation doped region 215. Another ion implantation process is then performed using another mask to implant the dopants of the second conductivity type (N-type) into the well region 207 and the region 203-3 of the second epitaxial layer 203L to form an emitter contact region 209 and a collector contact region 213.

Next, as shown in FIGS. 8A and 8B, photolithography and etching processes are performed to etch a plurality of alternating trenches 232 and strip structures 231 in the well region 207 and the second epitaxial layer 203L, and the area A between the emitter contact area 209 and the isolation doped area 215. By controlling the parameters of the etching process, the bottom surfaces of the trenches 232 are all higher than the bottom surfaces of the emitter contact area 209 and the isolation doped area 215. In some embodiments, the etching process includes dry etching. Dry etching may include plasma etching, plasma-free gas etching, sputter etching, ion milling, reactive ion etching (RIE), neutral beam etch (NBE), inductive coupled plasma etch or other suitable processes.

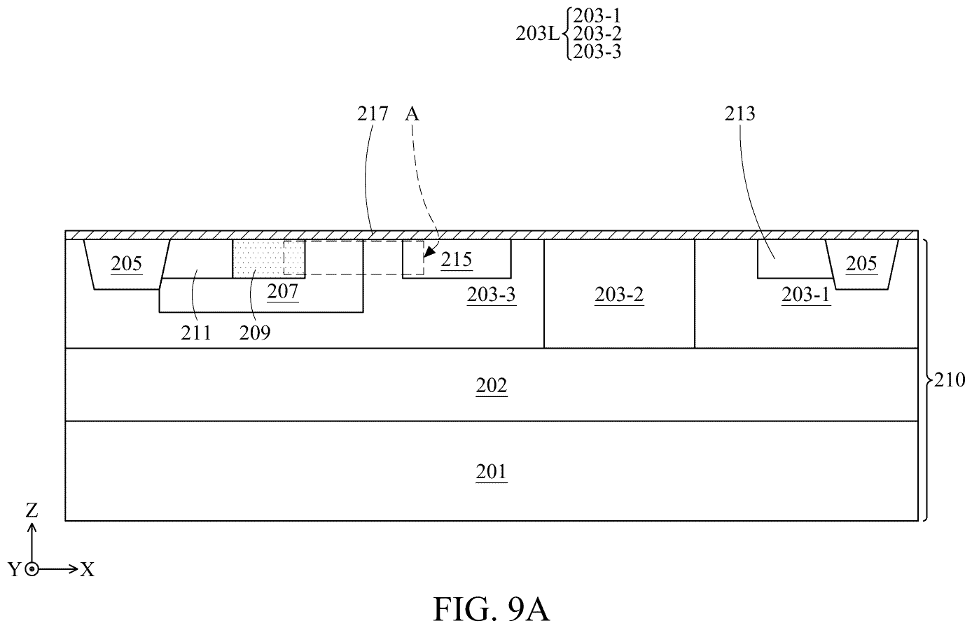

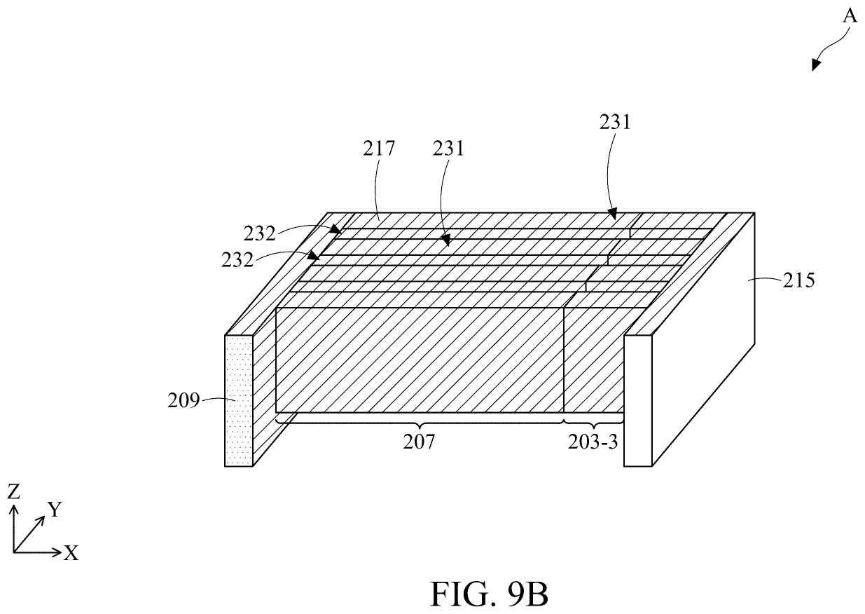

Next, as shown in FIGS. 9A and 9B, a gate dielectric layer 217, such as a silicon oxide layer, is conformally formed on the sidewalls and top surfaces of the strip structures 231, the bottom surfaces of the trenches 232, and the top surface of the substrate structure 210 by thermal oxidation or deposition process.

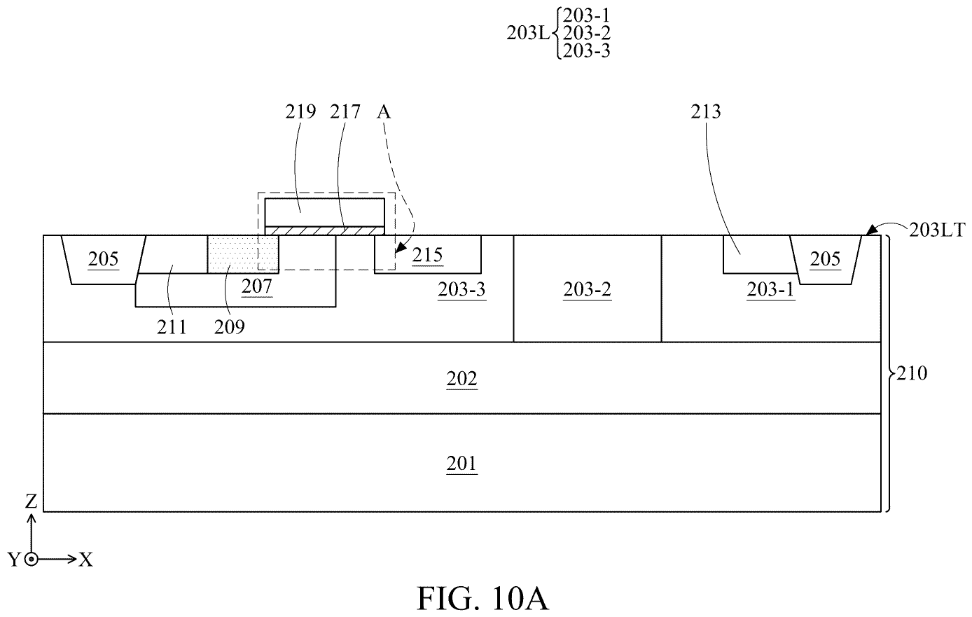

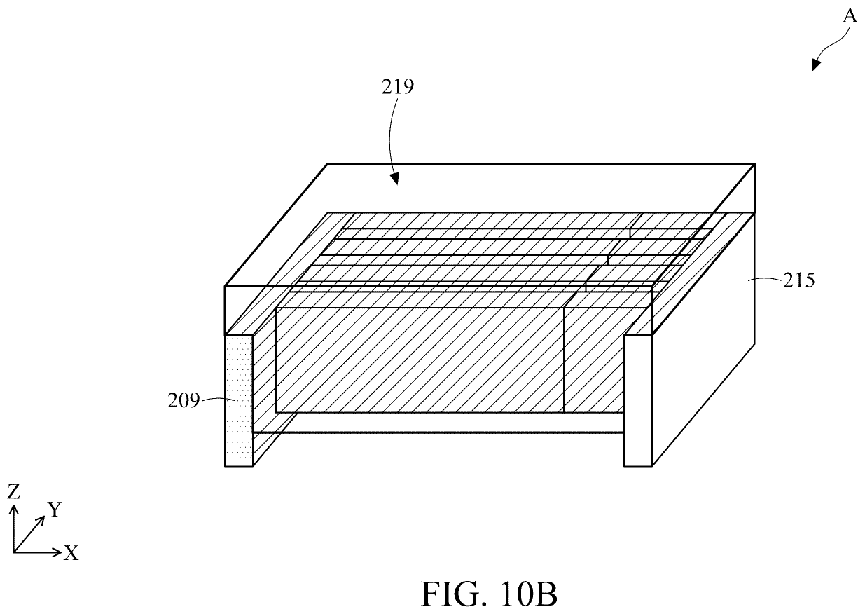

Next, as shown in FIGS. 10A and 10B, a gate material layer is deposited on the surface of the substrate structure 210 by deposition and chemical mechanical planarization processes, and the gate material layer fills the trenches 232. In some embodiments, the gate material layer is, for example, a polysilicon layer. An ion implantation process is performed using a mask to implant a second conductive type (N-type) dopant into the gate material layer to form an N-type doped polysilicon layer. Next, a photolithography process and an etching process are performed to pattern the N-type doped polysilicon layer, thereby forming a gate electrode 219.

In some embodiments, after forming the gate electrode 219, a thermal oxidation or deposition process may be performed to conformally form a dielectric layer (not shown), such as a silicon oxide layer, on the sidewalls and the top surface of the gate electrode 219 and the top surface of the substrate structure 210 (i.e., the top surface 203LT of the second epitaxial layer 203L). The dielectric layer may increase the adhesion between the surfaces of the substrate structure 210 and the gate electrode 219 shown in FIGS. 10A and 10B and the subsequent interlayer dielectric layer 220.

Next, as shown in FIG. 1, a backend process is performed to deposit an interlayer dielectric layer 220 on the substrate structure 210. Next, photolithography, etching and deposition processes are performed to from an emitter contact 221, a collector contact 223 and other contact plugs in the interlayer dielectric layer 220. Next, an emitter electrode 222, a collector electrode 224 and other conductive lines are formed on the interlayer dielectric layer 220. After the above-mentioned process, the semiconductor device 500 of FIG. 1 is formed.

Embodiments of the disclosure provide a semiconductor device (e.g., a lateral insulated gate bipolar transistor) and a method of forming the same. In accordance with some embodiments of the disclosure, a plurality of trenches (e.g., the trench 232) and a plurality of strip structures (e.g., the strip structure 231) are disposed alternately in a substrate structure (e.g., substrate structure 210) of a semiconductor device. The trenches and strip structures are located between an emitter region (e.g., the emitter contact region 209) and a collector region (e.g., the collector contact region 213). A gate (e.g., the gate electrode 219) is disposed on the substrate structure and fills the trenches to wrap the strip structures, thereby forming a three-dimensional channel structure. Without increasing the chip area, the channel width can be increased by a three-dimensional channel structure, and the channel mobility can be increased by utilizing the crystal plane of the sidewall of the strip structure, thereby reducing the on-resistance and increasing the forward current to improve the electrical performance of the semiconductor device. In addition, the drift region (the second epitaxial layer 203L) of the semiconductor device may have multiple regions having different doping concentrations so as to respectively arrange the three-dimensional channel structure and the collector region (the collector contact region 213) in different regions. On-resistance of the semiconductor device can be further reduced under the condition of the same breakdown voltage (or breakdown voltage of the semiconductor device can be further increased under the condition of the same on-resistance) by adjusting the doping concentrations of the above-mentioned regions.

Embodiment provides a semiconductor device. The semiconductor device includes a substrate structure, a well region, an emitter contact region, a collector contact region, an isolation doped region, trenches and a gate. The substrate structure includes a top epitaxial layer. The top epitaxial layer includes a first region and a second region. The well region is located outside the first region of the top epitaxial layer. The well region has a first conductivity type, and the top epitaxial layer has a second conductivity type. The emitter contact region is disposed on the well region. The collector contact region is disposed in the first region of the top epitaxial layer. The emitter contact region and the collector contact region have opposite conductivity types. The isolation doped region is disposed outside the first region of the top epitaxial layer and located between the well region and the collector contact region, and the isolation doped region has a first conductivity type. The trenches are disposed in the substrate structure. The trenches extend from the emitter contact region to the isolation doped region along a first direction. Bottom surfaces of the trenches are higher than a bottom surface of the emitter contact region and a bottom surface of the isolation doped region. The gate is disposed on the substrate structure and fills the trench. The distance between the collector contact region and the gate is greater than the distance between the emitter contact region and the gate. The first region and the second region of the top epitaxial layer have different doping concentrations.

In some embodiments, the emitter contact region has the second conductivity type, and the collector contact region has the first conductivity type.

In some embodiments, the well region and the isolation doped region are disposed in the second region of the top epitaxial layer.

In some embodiments, the doping concentration of the first region is less than the doping concentration of the second region.

In some embodiments, a first top surface of the first region and a second top surface of the second region are both different portions of a top surface of the top epitaxial layer, and a first bottom surface of the first region and a second bottom surface of the second region are both different portions of a bottom surface of the top epitaxial layer.

In some embodiments, the trenches are disposed in the second region of the top epitaxial layer.

In some embodiments, the top epitaxial layer further includes a third region. The second region is located between the first region and the third region along the first direction. A doping concentration of the second region is different from a doping concentration of the first region and a doping concentration of the third region.

In some embodiments, the well region and the isolation doped region are disposed in the third region of the top epitaxial layer.

In some embodiments, the doping concentration of the first region is the same as the doping concentration of the third region.

In some embodiments, a first interface between the second region and the first region and a second interface between the second region and the third region both extend from a top surface of the top epitaxial layer to a bottom surface of the top epitaxial layer along a second direction.

In some embodiments, the substrate structure includes a bottom layer and a middle epitaxial layer. The bottom layer has the second conductivity type. The middle epitaxial layer is disposed between the bottom layer and the top epitaxial layer, wherein the middle epitaxial layer has the first conductivity type.

In some embodiments, the substrate structure includes strip structures. The strip structures extend from the emitter contact region to the isolation doped region along a first direction. The strip structures and the trenches are alternately arranged along a third direction.

In some embodiments, the substrate structure is composed of silicon carbide or silicon, and each of sidewalls of the strip structures includes the (0, −3, 3, −8) crystal plane or the (1, 1, −2, 0) crystal plane of silicon carbide, or the (1, 0, 0) crystal plane of silicon.

In some embodiments, the semiconductor device further includes a shallow trench isolation structure. The shallow trench isolation structure is disposed in the substrate structure. Top surfaces of the strip structures, a top surface of the emitter contact region, a top surface of the isolation doped region, a top surface of the collector contact region and a top surface of the shallow trench isolation structure are all located on the same plane.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a substrate structure, wherein the substrate structure comprises a top epitaxial layer, wherein the top epitaxial layer comprises a first region and a second region;
a well region located outside the first region of the top epitaxial layer, wherein the well region has a first conductivity type and the top epitaxial layer has a second conductivity type;
an emitter contact region disposed on the well region;
a collector contact region disposed in the first region of the top epitaxial layer, wherein the emitter contact region and the collector contact region have opposite conductivity types;
an isolation doped region disposed outside the first region of the top epitaxial layer and located between the well region and the collector contact region, wherein the isolation doped region has the first conductivity type;
trenches disposed in the substrate structure, wherein the trenches extend from the emitter contact region to the isolation doped region along a first direction, and bottom surfaces of the trenches are higher than a bottom surface of the emitter contact region and a bottom surface of the isolation doped region; and
a gate electrode disposed on the substrate structure and filling the trenches, wherein a distance between the collector contact region and the gate electrode is greater than a distance between the emitter contact region and the gate electrode, and
wherein the first region and the second region of the top epitaxial layer have different doping concentrations.

2. The semiconductor device as claimed in claim 1, wherein the emitter contact region has the second conductivity type, and the collector contact region has the first conductivity type.

3. The semiconductor device as claimed in claim 1, wherein the well region and the isolation doped region are disposed in the second region of the top epitaxial layer.

4. The semiconductor device as claimed in claim 1, wherein a doping concentration of the first region is less than a doping concentration of the second region.

5. The semiconductor device as claimed in claim 1, wherein a first top surface of the first region and a second top surface of the second region are both different portions of a top surface of the top epitaxial layer, and a first bottom surface of the first region and a second bottom surface of the second region are both different portions of a bottom surface of the top epitaxial layer.

6. The semiconductor device as claimed in claim 1, wherein the trenches are disposed in the second region of the top epitaxial layer.

7. The semiconductor device as claimed in claim 1, wherein the top epitaxial layer further comprises:
a third region, wherein the second region is located between the first region and the third region along the first direction, and a doping concentration of the second region is different from a doping concentration of the first region and a doping concentration of the third region.

8. The semiconductor device as claimed in claim 7, wherein the well region and the isolation doped region are disposed in the third region of the top epitaxial layer.

9. The semiconductor device as claimed in claim 7, wherein the doping concentration of the first region is the same as the doping concentration of the third region.

10. The semiconductor device as claimed in claim 7, wherein a first interface between the second region and the first region and a second interface between the second region and the third region both extend from a top surface of the top epitaxial layer to a bottom surface of the top epitaxial layer along a second direction.

11. The semiconductor device as claimed in claim 1, wherein the substrate structure comprises:
a bottom layer having the second conductivity type; and
a middle epitaxial layer disposed between the bottom layer and the top epitaxial layer, wherein the middle epitaxial layer has the first conductivity type.

12. The semiconductor device as claimed in claim 1, wherein the substrate structure comprises strip structures, wherein the strip structures extend from the emitter contact region to the isolation doped region along the first direction, and the strip structures and the trenches are alternately arranged along a third direction.

13. The semiconductor device as claimed in claim 12, wherein the substrate structure is composed of silicon carbide or silicon, and each of sidewalls of the strip structures comprises a (0, −3, 3, −8) crystal plane or a (1, 1, −2, 0) crystal plane of silicon carbide, or a (1, 0, 0) crystal plane of silicon.

14. The semiconductor device as claimed in claim 12, further comprising:
a shallow trench isolation structure disposed in the substrate structure, wherein top surfaces of the strip structures, a top surface of the emitter contact region, a top surface of the isolation doped region, a top surface of the collector contact region and a top surface of the shallow trench isolation structure are all located on the same plane.
